(19) United States
(12) Patent Application Publication
(10) Pub. No.: US 2012/0156100 A1
(43) Pub. Date: Jun. 21, 2012

(54) APPARATUS FOR SINGLE MOLECULE DETECTION AND METHOD THEREOF

(75) Inventors: Rung-Ywan Tsai, Taipei City (TW); Cheng-Wei Chu, Taipei County (TW); Hsiu-Hsiang Chen, Hsinchu County (TW)

(73) Assignee: INDUSTRIAL TECHNOLOGY RESEARCH INSTITUTE, Hsinchu (TW)

(21) Appl. No.: 12/972,546

(22) Filed: Dec. 20, 2010

(51) Int. Cl. G01N 21/64; H01L 21/77; B82Y 99/00; B82Y 40/00

(52) U.S. Cl. 422/82.08; 438/49; 977/759; 977/840

(57) ABSTRACT

The present invention directs to a detection apparatus for detecting the fluorescence signal emitting from a single and individual analyte molecule. By integrating the excitation light source, the detector array and the nanowell array all together within the detection apparatus, the single analyte molecule trapped in the nanowell can be excited by the light source and emits fluorescence signal to the detector array.

### BACKGROUND

1. Technical Field

The disclosure relates to a detection method. More particularly, the disclosure relates to a detection apparatus of a single analyte molecule and the preparation method thereof.

2. Related Art

For most of the single molecule detection apparatus, one and only one analyte molecule is analyzed. In order to guarantee that only one analyte molecule in the volume is probed by the excitation light and provide good signal to noise ratio (SNR) and signal to background (SBR) for detection, the excitation light is generally focused to a small probe volume allowing single analyte molecule existed. For practical analyses, the physiological concentration of the analyte is always higher than 1 micromolar and the effective probe volume is therefore should be smaller than 1 atoliter (10⁻¹⁸ L). Within such a confinement volume, the fluorescence signal emitting from the single analyte molecule excited by the excitation light is weak and difficult to be captured by the detector.

### SUMMARY

The disclosure related to a highly integrated apparatus for detecting the fluorescence signal emitting from the single analyte molecule and the manufacturing processes thereof.

As embodied and broadly described herein, the apparatus includes a plurality of detectors disposed in the substrate, an opaque layer has a plurality of optical windows on the substrate, and the optical windows align with the detectors, an excitation light source on the opaque layer, and a plurality of nanowells in the excitation light source for trapping a single molecule. The single molecule in the nanowell is excited by the excitation light source and emits a fluorescence signal that is detected by the detector underneath the nanowell.

As embodied and broadly described herein, the present invention directs to methods for manufacturing an apparatus for single molecule detection. After providing a substrate having a plurality of detectors therein, an opaque layer with a plurality of optical windows is formed on the substrate. One of the optical windows corresponds to one of the detectors. After forming a photoresist pattern on the opaque layer, an excitation light source is deposited on the opaque layer and the photoresist pattern. A first protection layer is formed over the excitation light source. Then, a plurality of nanowells is formed in the excitation light source.

In order to make the aforementioned and other objects, features and advantages of the present invention comprehensible, embodiments accompanied with figures are described in detail below. It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the description, serve to explain the principles of the disclosure.

FIG. 1 is a cross-sectional view of a single molecule detection apparatus according to an embodiment.

FIG. 2 is a cross-sectional view of a single molecule detection apparatus according to another embodiment.

FIG. 3 is a cross-sectional view of a single molecule detection apparatus according to another embodiment.

FIG. 4 is a cross-sectional schematic view of a single molecule detection apparatus according to one embodiment.

FIG. 5 is a cross-sectional schematic view of a single molecule detection apparatus according to another embodiment.

FIG. 6 is a cross-sectional schematic view of a single molecule detection apparatus according to another embodiment.

FIG. 7 is a cross-sectional schematic view of a single molecule detection apparatus according to another embodiment.

FIG. 8 is a cross-sectional schematic view of a single molecule detection apparatus according to another embodiment.

FIG. 9 is a cross-sectional schematic view of a single molecule detection apparatus according to another embodiment.

FIG. 10 is a cross-sectional schematic view of a single molecule detection apparatus according to another embodiment.

FIGS. 11A-11I are cross-sectional views showing the fabricating process steps of the detection apparatus according one embodiment.

FIGS. 12A-12F are cross-sectional views showing the fabricating process steps of the detection apparatus according another embodiment.

### DESCRIPTION OF EMBODIMENTS

The embodiments are described below in detail with reference to the accompanying drawings, and the embodiments are shown in the accompanying drawings. However, the embodiments can also be implemented in a plurality of different forms, so it should not be interpreted as being limited in the following embodiments. Actually, the following embodiments are intended to demonstrate and illustrate in a more detailed and completed way, and to fully convey the embodiments to those of ordinary skill in the art. In the accompanying drawings, in order to be specific, the size and relative size of each layer and each region may be exaggeratedly depicted.

It should be known that although “upper”, “lower”, “top”, “bottom”, “under”, “on”, and similar words for indicating the relative space position are used in the disclosure to illustrate the relationship between a certain element or feature and another element or feature in the drawings. It should be known that, beside those relative space words for indicating the directions depicted in the drawings, if the element/structure in the drawing is inverted, the element described as “upper” element or feature becomes “lower” element or feature.

Herein, “single molecule” may refer to a single and individual analyte molecule. The analyte molecule may be a single biomolecule, organic molecule or inorganic molecule as the light emitting object, or a single and individual biomolecule/organic molecule/inorganic molecule labeled with a light emitting object or a cluster of light emitting objects. Under certain circumstances, the analyte may be a cluster of molecules labeled a cluster of light emitting objects. The light emitting object may be a fluorophore, a phosphorophore, a quantum dot, a light emitting nanoparticle, or a light scattering particle.

In order to increase the detected SNR and SBR, four ways are considered to increase the fluorescence signal: (1) enhance the local excitation light intensity, (2) increase the fluorophore emission rate and quantum efficiency, (3) modify the emission pattern and direct it toward the detector, and (4) reduce the light path between the analyte and the detector. The excitation light intensity can be enhanced by concentrating and focusing the light into the effective excitation zone, which also offer the advantage reducing the noise induced from the impurities and/or defects outside of the effective excitation zone.

The major concerns of the integrated apparatus for single molecule detection include the process compatibility between the light source and the detector, the guiding and concentrating of the excitation light, the field intensity of the excitation light, and the directing and detecting of the emitted fluorescence signal into the detector.

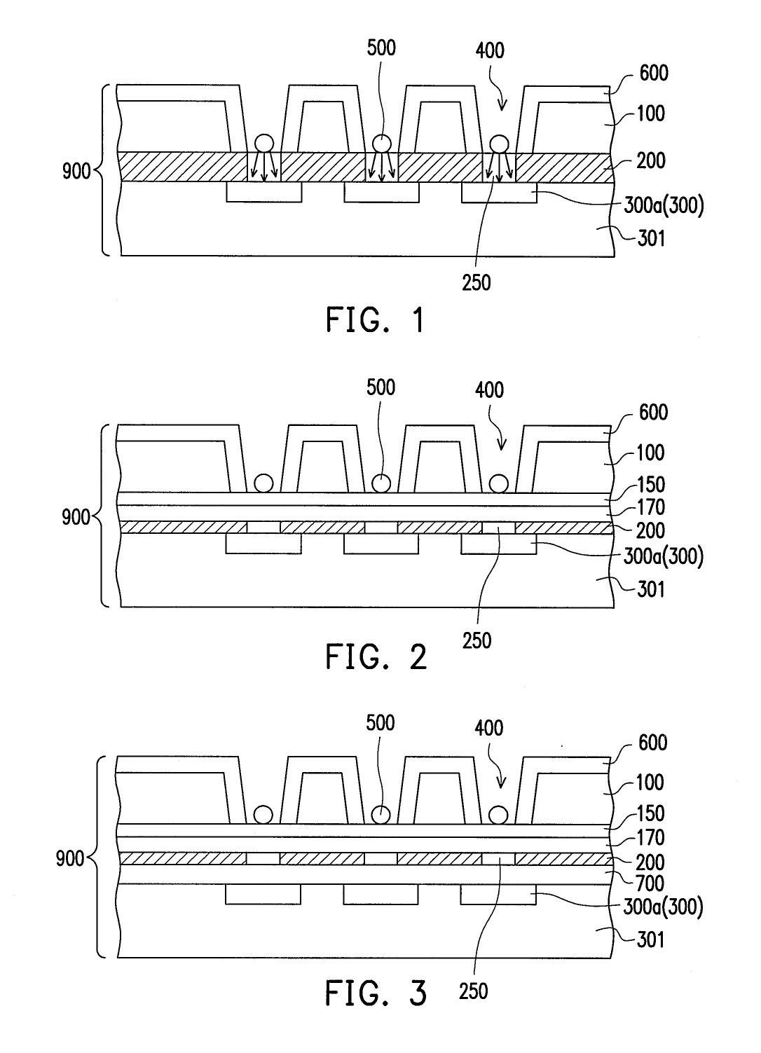

Herein, a highly integrated, single molecule detection apparatus is proposed. FIG. 1 is a cross-sectional schematic view of a single molecule detection apparatus according to an embodiment. As shown in FIG. 1, the apparatus 900 comprises a plurality of detectors 300a (arranged in array; may be noted as detector array) disposed on the substrate 301, an opaque layer 200 with optical windows 250 disposed on detector array 300a, an excitation light source 100 on the opaque layer 200, a plurality of nanowells 400 (arranged in array; may be noted as nanowell array) formed within the excitation light source 100 and located on the optical windows 250, and a protection layer 600 on the excitation light source 100 and covering the sidewalls of the nanowells 400. In fact, the detector array 300a is composed of a plurality of photodetectors 300 arranged in array. The locations of the nanowells 400, the optical windows 250 and the photodetectors 300 are aligned and arranged in arrays. That is, the optical window 250 is located directly on top of the photodetector 300 and the bottom of the nanowell 400 is located directly on top of the optical window 250. The single molecule 500 can be trapped in the nanowell 400 and get excited by the light emitting from the excitation light source 100. The fluorescence signal (shown as arrows) of the single molecule 500 passes through the optical window 250 and reaches the photodetector array 300a.

The excitation light sources applicable for single molecule detection apparatus include laser diode (LD), solid state pumped LD, light emitting diode (LED), organic light emitting diode (OLED), polymer light emitting diode (PLED), and quantum dot light emitting diode (QLED). The excitation light source 100 can be formed on top of the opaque layer 200 by deposition or other applicable technology.

The excitation light source can be solid state LD, including ultraviolet or blue LD based on GaN, green LD based on InGaN, red LD based on AlGaAs, or the solid state LD made by other materials. The excitation light source can be LED, including blue or green LED of AlInGaN or AlGaInN, orange LED of AlGaInP, red or Infrared LED of AlGaAs, or the solid state LED made by other materials. The excitation light source can be OLED, including blue OLED based on anthracene derivatives, green OLED based on Alq3, red OLED based on Alq3 doped with DCM2, or the solid state OLED made by other materials. The excitation light source can be PLED, including blue PLED based on poly(p-phenylene) (PPP), green PLED based on poly(2-methoxy-5(2-ethyl)hexoxy-phenylenevinylene) (MEH-PPV), red PLED based on poly(3-octylthiophene) (P3OT), or the solid state PLED made by other materials. The excitation light source can be QLED, including CdSe QLED with the emission light wavelength depending on the size of CdSe quantum dot, or the solid state QLED made by other materials.

Detectors or photodetectors used in here can be photodiode, charge coupled device (CCD), CMOS sensor, photoconductive type optical sensor, photovoltaic type optical sensor, avalanche photodiode (APD), p-n photodiode, p-i-n photodiode, multi junction photodiode. Most of the stray light induced by the excitation light source 100 and other noises can be blocked by the opaque layer 200.

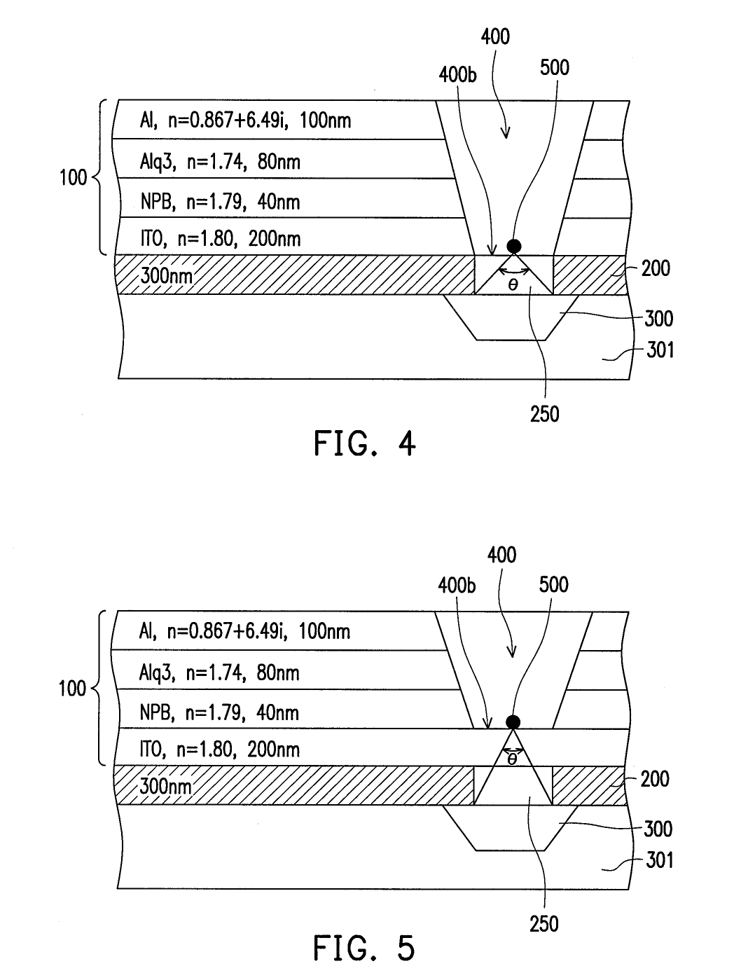

FIG. 2 is a cross-sectional schematic view of a single molecule detection apparatus according to another embodiment. The single-molecule detection apparatus 900 further includes a waveguide lower cladding layer 170 on the opaque layer 200, and a waveguide core layer 150 disposed on the waveguide lower cladding layer 170 for propagating excitation light. The excitation light source 100 is located on the waveguide core layer 150, so that a part of the generated excitation light from the excitation light source 100 can be routed and guided in the waveguide core layer. The waveguide lower cladding layer 170 on the opaque layer 200 can avoid the metal absorption loss of the excitation light of the waveguide core layer 150. The nanowell array 400 is disposed within the excitation light source 100 for accommodating single molecule and the bottom of the nanowell is situated at the top surface of the waveguide core layer 150. The single molecule 500 can be located at the nanowell bottom to receive light emitting from the excitation light source 100 and light propagating along the waveguide core layer 150.

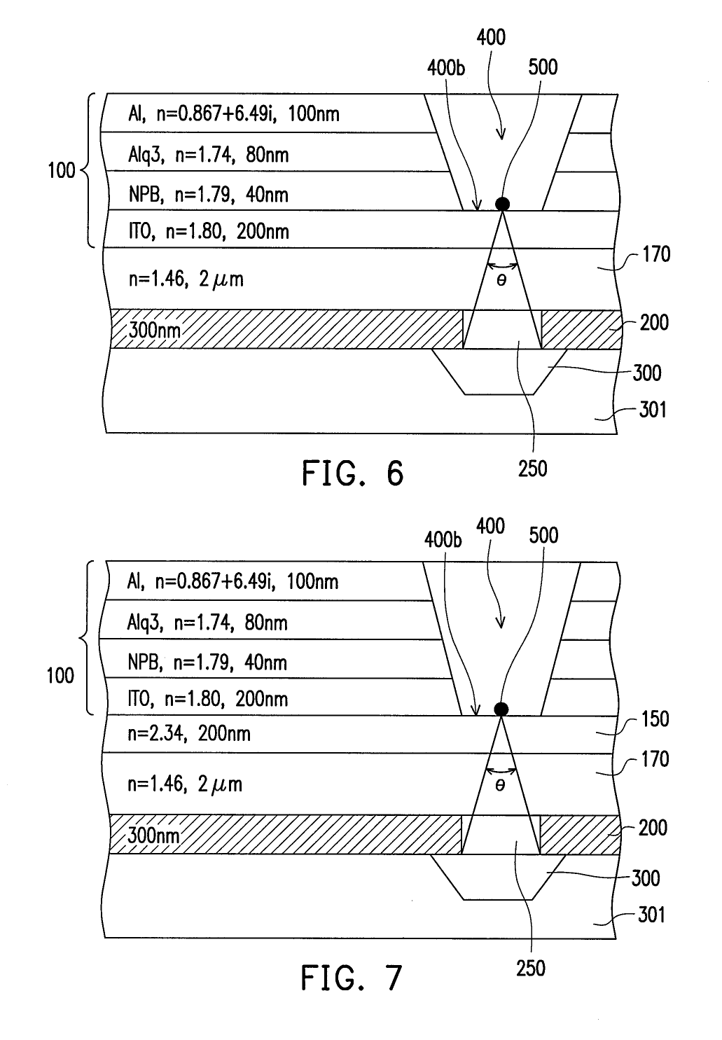

FIG. 3 is a cross-sectional schematic view of a single molecule detection apparatus according to another embodiment. The single-molecule apparatus 900 further includes a long-wave pass filter 700 disposed between the opaque layer 200 and substrate 301. As part of the stray light induced by the excitation light source and other noises may pass through the optical window of the opaque layer with the fluorescence signal and be detected by the photodetector, which degrades the signal-to-noise ratio (SNR). The long-wave pass filter can filter the undesirable light and enhance the SNR. The long-wave pass filter can be made by multilayer stacking with alternation of high- and low-refractive index dielectric materials. The commonly used high-index materials can be TiO₂, Ta₂O₅, Nb₂O₅, ZrO₂, HfO₂, Si₃N₄, or Si, and the low refractive index-materials can be CaF₂, MgF₂, SiO₂, Al₂O₃, PMMA, PC, or Su8, for example. The filters can be manufactured by physical vapor deposition, chemical vapor deposition, spin coating, or dipping.

An effective excitation zone at the nanowell bottom is defined by the emissive layer thickness of excitation light source. The single molecule entering the effective excitation zone is excited and emits fluorescence signal, and the emitted fluorescence signal captured by the photodetector located underlying the nanowell is transformed into an electrical signal.

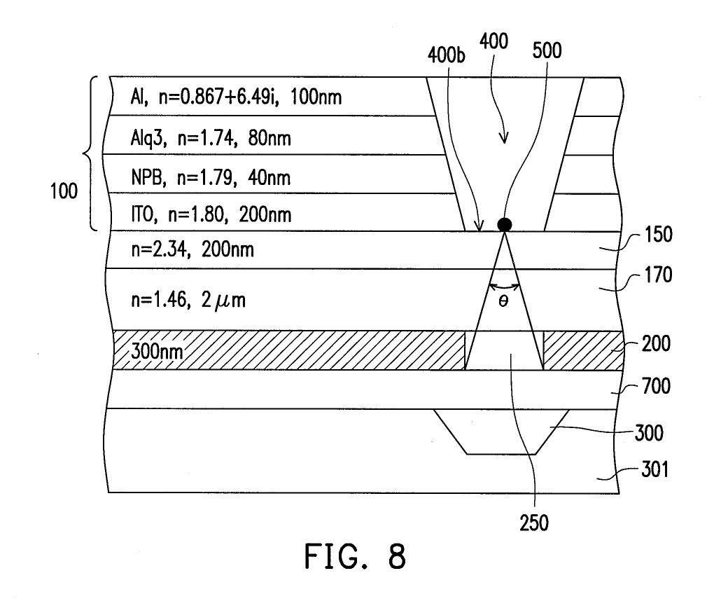

FIG. 4 is a cross-sectional schematic view of a single molecule detection apparatus according to another embodiment, using OLED as an example of the excitation light source. The structure of OLED (as an example of excitation light source 100) with the green excitation light of Alq3 is shown in FIG. 4. In general, the structure of OLED includes at least an anode layer (e.g. indium tin oxide (ITO) layer), emissive layer(s) and a cathode layer (e.g. Al). It has been reported that about 32% and 41% of emission light are respectively guided by emissive/ITO layers and substrate, when the low index (n=1.53) glass substrate is used. Only 27% of emission light is extracted from the OLED device. If the high index (n>1.8) waveguide core layer (<200 nm thick) is used to replace the glass substrate, the excitation light guided inside the device will be increased due to most of the excitation light is guided within the waveguide core layer. However, the excitation light guided within the thin layer of core is inferior to that of thick glass substrate due to the thickness effect. Therefore, the efficiency of the excitation light guided within the OLED device is a compromise between the core index and thickness effect.

In FIG. 4, the light irradiated from the emissive layers of OLED shines on the single molecule 500 that is located at the bottom of the nanowell 400. The bottom 400b of the nanowell 400 is located at the top surface of the opaque layer 200 and is located right above the optical window 250 of the opaque layer 200. Herein, the dimension of the nanowell bottom is substantially the same as that of the optical window 250 of the opaque layer 200. The single molecule 500 can be excited by the sidelight of OLED and the fluorescence emitted from the single molecule 500 can be received by the detector 300 located under the nanowell bottom and transformed into an electronic signal. The shape of the nanowell 400 may be like a circular funnel with a larger top opening has a diameter large than 1 μm and a smaller bottom has a diameter less than 200 nm.

For example, the irradiance of OLED using Alq3 as an emissive layer is equal to 100 W/cm² irradiated at the single molecule of CY3. The quantum efficiency and absorption cross section of CY3 are 0.07 and 3.64×10⁻¹⁶-cm² at the wavelength of 530 nm. Therefore, the emitted fluorescence of CY3 is equal to 2.55×10⁻¹⁵ W. However, the amount of emitted fluorescence light emitted from single molecule fluorophore and captured by the photodetector is decided by the collection angle θ. When the photodetector 300 is positioned directly under the optical window 250 of opaque layer 200 as shown in FIG. 4, the estimated photons arriving at the photodetector are:

N=I₀×Ω/4π (1)

where N is photons arriving at the photodetector, I₀ is power of emitted fluorescence light, and Ω is the solid angle. The solid angle can be calculated from the collection angle θ:

Ω=4×sin⁻¹(sin(θ/2))² (2)

In order to avoid the OLED excitation light directly irradiating into photodetector, the dimension of the optical window 250 of the opaque layer 200 should be substantially the same as or smaller than that of the nanowell bottom. When the dimension of the optical window 250 is substantially the same as that of the nanowell bottom, the collection angle θ of photodetector 300 is 18.5° and the photons N arriving at the photodetector is 6.8 for 30 msec integration time, as shown in FIG. 4.

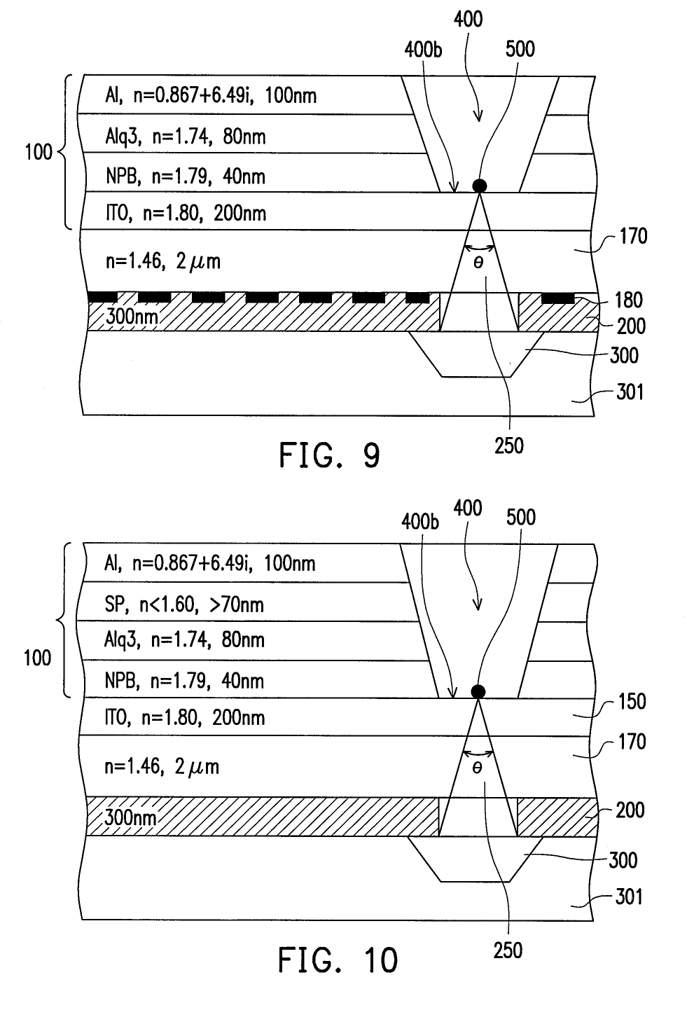

In FIG. 5, the bottom 400b of the nanowell 400 is located at the top surface of the ITO layer and right above the optical window 250 of the opaque layer 200. The single molecule 500 at the nanowell bottom 400b is located right on the top surface of ITO layer, the collection angle θ of photodetector 300 is 11.3° and less photons N of 2.63 is arriving at the photodetector for 30 msec integration time.

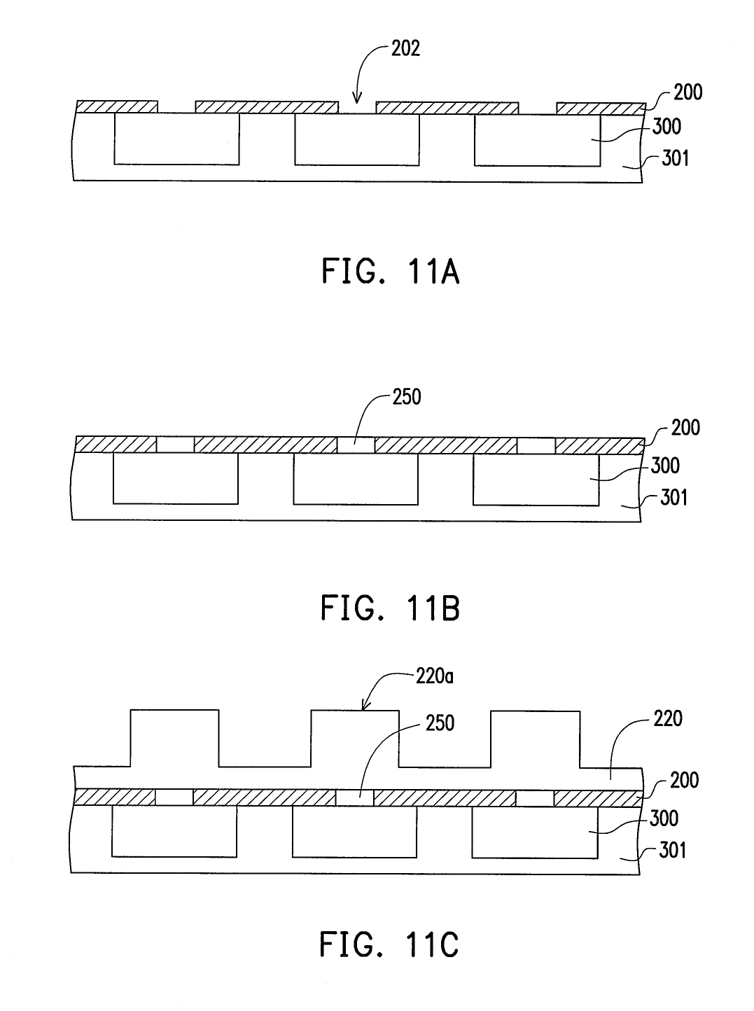

In another embodiment, the single molecule 500 is excited by the evanescent wave induced by the light propagating along the waveguide core layer and/or the light wave directly irradiated from the emissive layers of OLED in FIG. 6. For example, a low-index SiO₂ layer is deposited between the ITO and opaque layers as a waveguide lower cladding layer 170. In this case, a part of the excitation light from OLED is guided and propagating within the ITO layer. With the aid of evanescent wave induced by the excitation light propagating along the waveguide core layer (i.e. ITO), the intensity of the fluorescence emitted from the single molecule 500 can be increased.

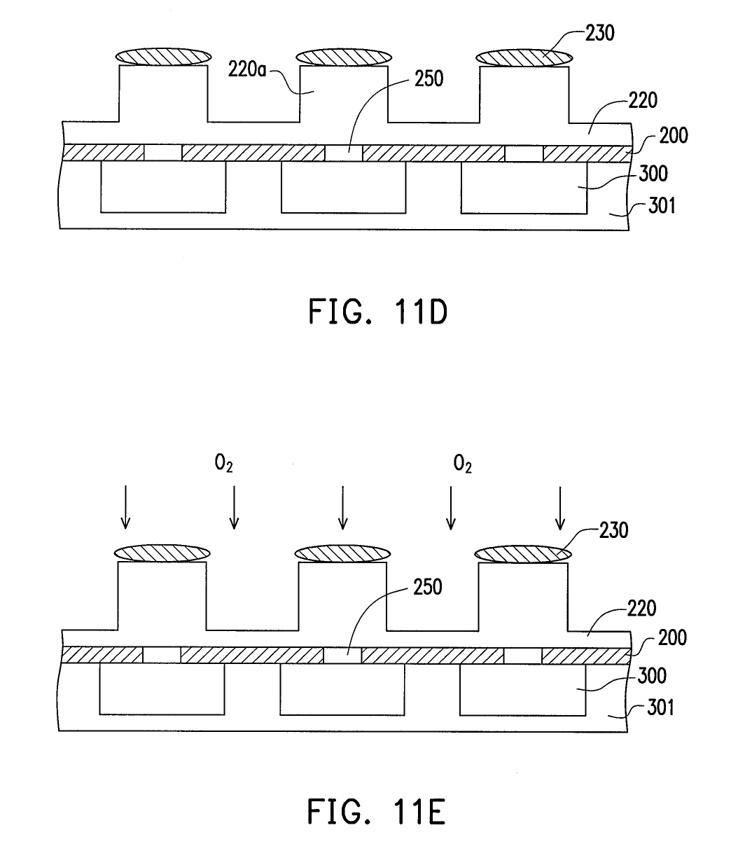

As discussed above, the excitation light guided within the waveguide core layer can be increased if another high index core layer is added due to the strong guiding efficiency of the high index layer and the increase guiding layer thickness. FIG. 7 shows that a Ta₂O₅ layer as a waveguide core layer 150 is deposited between the lower cladding layer 170 and ITO layer. The nanowell bottom 400b is located at the top surface of the waveguide core layer 150. Since the refractive index of Ta₂O₅ is 2.34 at 530 nm, the ratio of the excitation light guiding within the waveguide core layer is increased and the induced evanescent field is increased. Similarly, the intensity of the fluorescence light emitted from single molecule fluorophore 500 is increased.

The stray light caused by the surface scattering of the excitation light propagating within the waveguide core layer 150 shown in FIG. 7 can be received by the photodetector as a noise Ns:

Ns=I_{0S}×S×Ω/4π (3)

where S is the surface scattering which is equal to

S=(4π×σ/λ)² (4)

when the dimension D and surface roughness a of the optical window respectively is 200 nm and 0.3 nm, the noise Ns coming from the stray excitation light is

Ns=100×0.03×[(π×(D/2)²]×(4π×σ/λ)²×Ω/4π (5)

The calculated Ns is 8 photons, which is about the same order of the detected fluorescence signal.

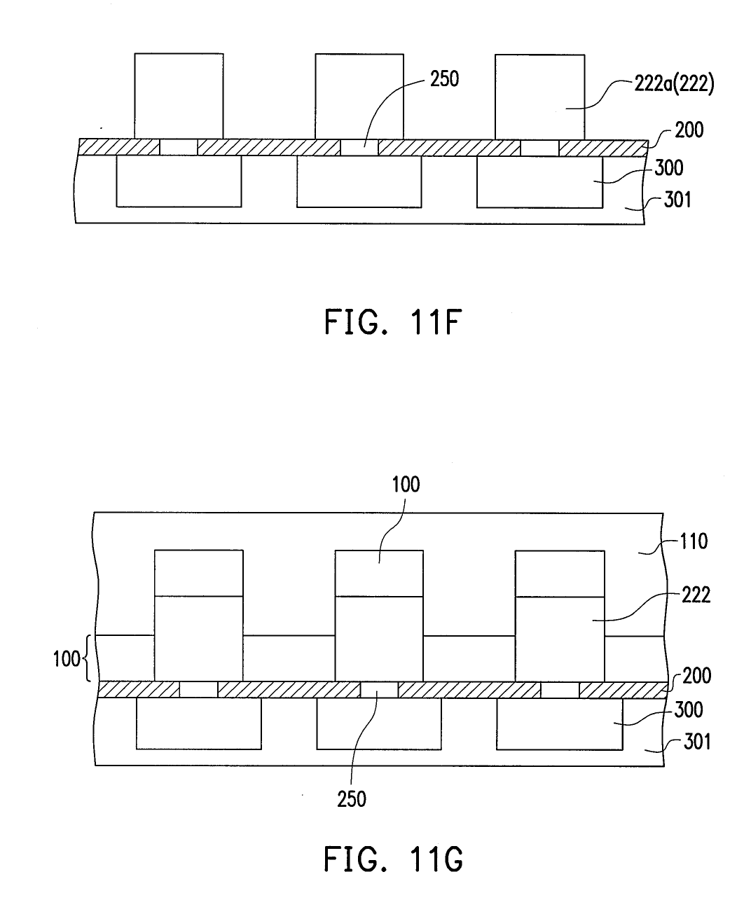

Therefore, a long-wave pass filter (LPF) 700 with the extinction ratio (the transmittance ratio of the stop band to the pass band) of 10⁻² is deposited between the opaque layer 200 and the substrate 301 to cutoff the stray light and increase the SNR up to 100 as shown in FIG. 8. If the dimension D of the optical window 250 is increased to 8.66 μm, the fluorescence signal N is increased to 58 photons. However, the stray light noise Ns is greatly increased up to 6.63×10⁷ photons, which is much greater than the detected fluorescence signal. Therefore, a LPF with the extinction ratio (the transmittance ratio of the stop band to the pass band) of 10⁻⁸ must be used to cutoff the stray excitation light and the SNR is improved to 100 (suitable for distinguishing signal).

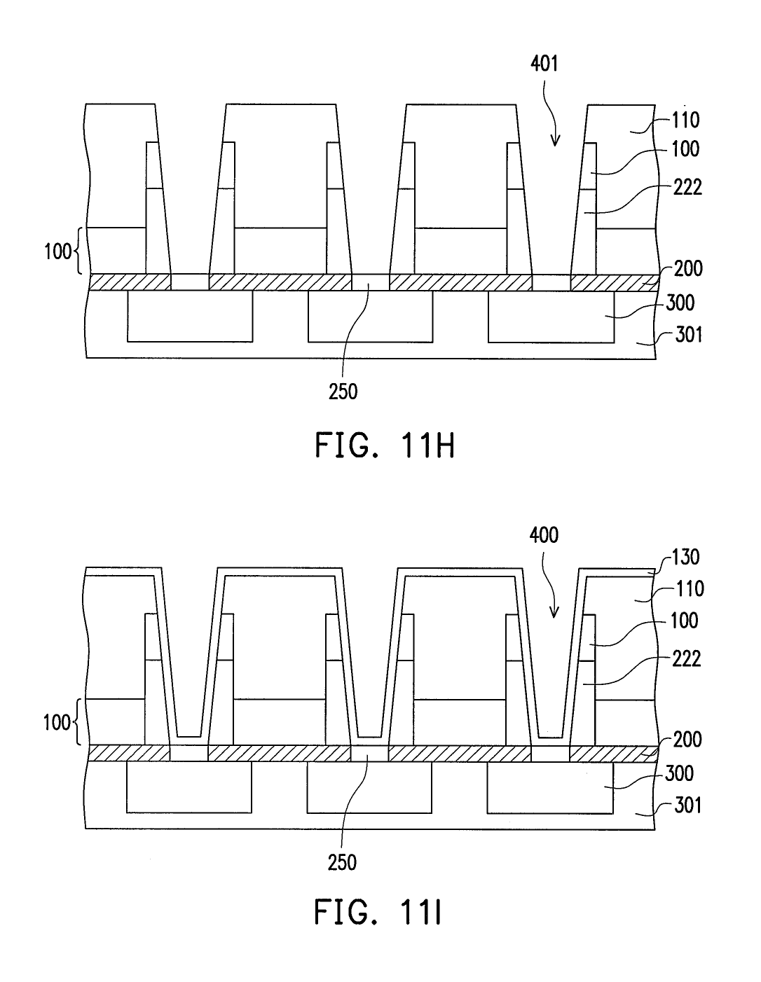

In order to increase the emission light guided in the waveguide core layer, a microstructured pattern 180 (as a raster) is disposed at the interface between the opaque layer 200 and the waveguide lower cladding layer 170 and surrounding the optical windows 250 as shown in FIG. 9. The purpose is to recycle the emission light from the OLED nearly perpendicular to the surface, which will be diffracted back by the microstructured pattern and guided within the waveguide core layer. The evanescent efficiency of the excitation light can be therefore increased and the emitted fluorescent light intensity is also increased.

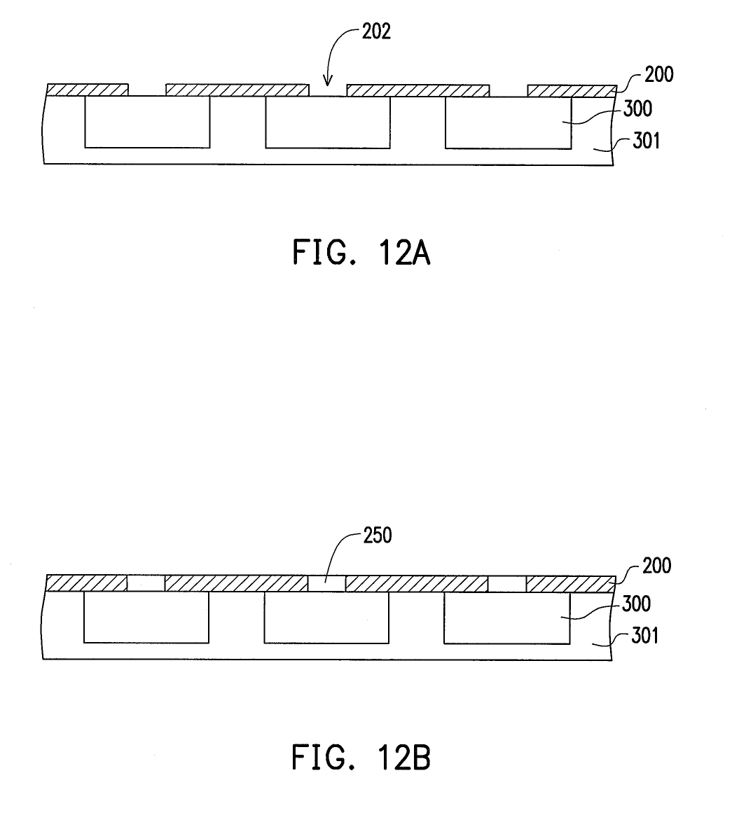

Alternatively, a separation layer (SP) about 70 nm thick with the low refractive index (n<1.6) is disposed between the Al layer and Alq3 layer as shown in FIG. 10. It has been reported that the fluorophore quenching occurring in close proximity to metallic surface (<5 nm) can be avoided by using a separation layer without absorption. With the aid of the SP layer, the light propagating within the ITO waveguide layer and the waveguide lower cladding layer and the evanescent field intensity at the nanowell bottom are increased.

Herein, the array of nanowells is fabricated by forming microwells penetrating into the excitation light source stacked layer. The depth of the nanowell (i.e. the location of the nanowell bottom) or the density of the nanowell per unit substrate area can be adjusted according to the sensitivity requirements. The nanowells can be arranged in array of circular, square, triangle, rectangle, or polygonal shapes. The shape of the top opening of the nanowell can be circular, square, triangle, rectangle, or polygonal. Depending on the location, size and shape of the nanowell bottom, an effective excitation zone is constructed. The single molecule is excited when entering the effective excitation zone. The effective excitation zone (volume) can be designed as small as a few zepto-liters to one atto-liter.

The nanowell bottom can be located either on the top surface of the waveguide core layer for the maximum evanescent field intensity or at the levels of the emissive layer for the maximum radiation field intensity.

However, the performance of the excitation light source is quite sensitive to the atmosphere and the nanowells cannot be formed by directly drilling into the excitation light source stacked layer. In order to preclude the unfavorable factors, including water, oxygen, chemicals, energetic ion bombardment and heat, the nanowell shall be isolated from the atmosphere or the outer environment by a protection layer.

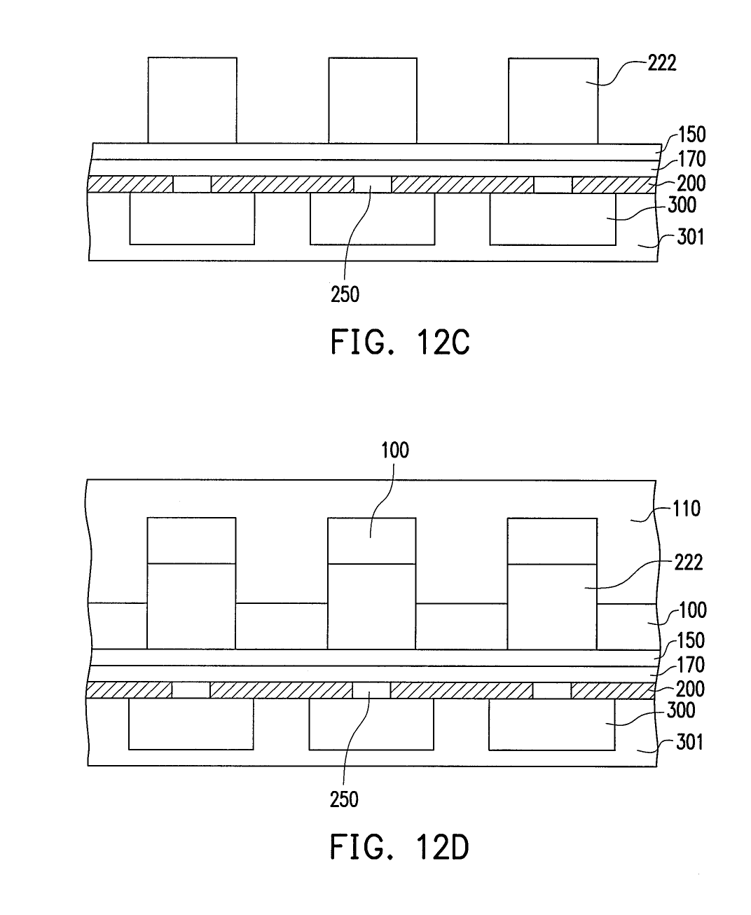

FIGS. 11A-11I are cross-sectional views showing the fabricating process steps of the detection apparatus according one embodiment. According to this embodiment, the excitation light source is OLED with the structure shown in FIG. 4. As shown in FIG. 11A, a substrate 301 having photodetectors 300 is provided. An opaque layer 200 of a thickness about 300 nm is coating on the top surface of the substrate 301 by vacuum deposition. Then, a plurality of holes 202 is formed in array within the opaque layer 200. The material of the opaque layer 200 can be Al doped with Ti, or other metal materials, including Al, Ti, Cr, Ag, Au, Ni, Cu, In, Pt, Pd, C, Si, Ge and Ga.

Referring to FIG. 11B, a transparent low index material layer (not shown) is formed over the opaque layer 200 to fill up the holes 202. The holes 202 filled with the transparent low index material (such as SiO₂) become optical windows 250.

Referring to FIGS. 11C-D, a patterned photoresist layer 220 is formed on the top surface of the opaque layer 200. Later, a thin Cr layer 230 of a thickness about 10 nm is deposited on the protruded portions 221 of the patterned photoresist layer 220 as a mask. As shown in FIG. 11E, an oxygen plasma (shown as arrows) is used to etch the unprotected photoresist layer 220 away, so that the photoresist pattern 222 (including a plurality of pillar pattern 222a) is obtained right on the optical windows of the opaque layer. Later, in FIG. 11F, the Cr mask 230 is removed.

Referring to FIG. 11G, the excitation light source 100 consisting of sequentially stacked layers of ITO (200 nm), NPB (40 nm), Alq3 (80 nm) and Al (100 nm) is deposited by evaporation over the opaque layer 200 and the photoresist pattern 222. Then, a protection layer 110 (50 nm) is deposited on the excitation light source 100 to protect the excitation light source stacked layers. The preferred material of the protection layer is Al₂O₃. However, other materials such as Al, Ti, Cr, Ag, Au, Ni, Cu, Pt or Pd, and metal oxides, such as SiO₂, TiO₂, ZrO₂, HfO₂, Ta₂O₅, Nb₂O₅ are also used.

As shown in FIG. 11H, a plurality of microwells 401 is formed by drilling through the excitation light source stacked layer 100 and the photoresist pattern 222 using a focused ion beam, for example. The locations of the microwells 401 correspond to the locations of the optical windows 250.

In FIG. 11I, another protection layer 130 (e.g. an Al₂O₃ layer of 50 nm) is deposited conformally over the microwells 401 by atomic deposition, so as to obtain a plurality of nanowells 400. The protection layer 130 conformally covers the sidewalls and the bottoms of all the nanowells 400. Due to the protection layers, excellent isolation of water and oxygen can be achieved.

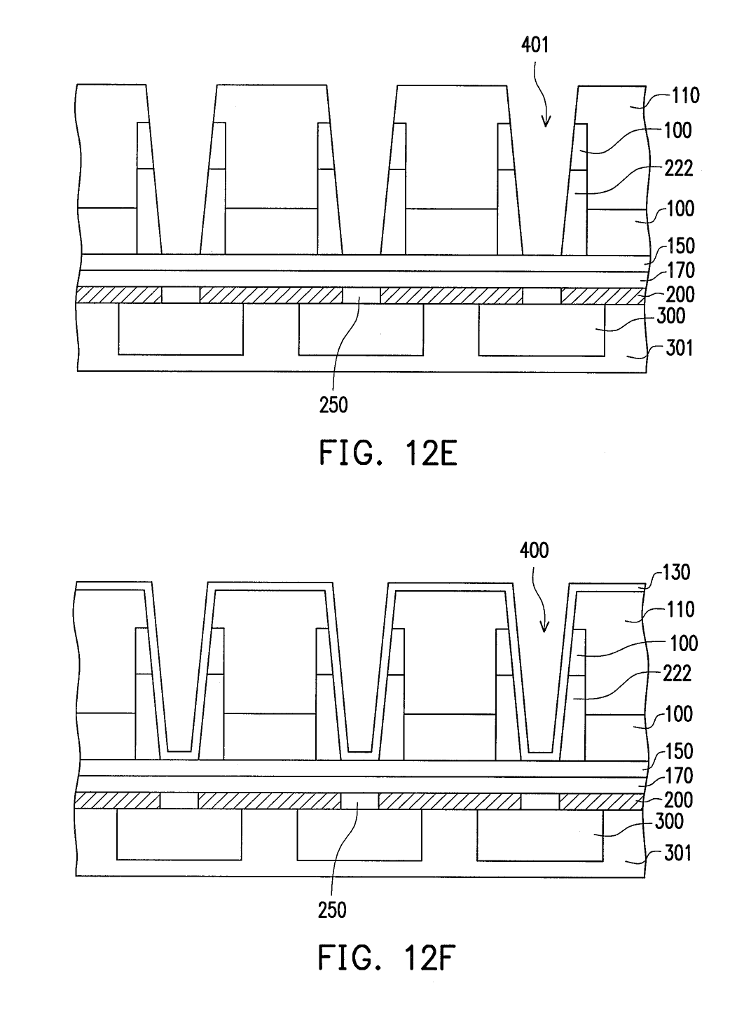

FIGS. 12A-12F are cross-sectional views showing the fabricating process steps of the detection apparatus according one embodiment. According to this embodiment, the excitation light source is OLED with the structure shown in FIG. 6.

Except for the additionally formed layer, most of the process steps in this embodiments are similar to those steps described above and will not be described in details in the following paragraphs. In FIGS. 12A-12B, an opaque layer 200 with a plurality of optical windows 250 is formed on the substrate 301 with photodetectors 300. The photodetectors can be photodiodes arranged in array, for example. The materials and/or the methods are similar to the details described in FIGS. 11A-11B.

In FIG. 12C, a waveguide lower cladding index layer 170 is deposited on the opaque layer 200. The waveguide lower cladding index layer 170 is a silicon dioxide layer of about 2 μm, for example. Alternatively, other materials such as CaF₂, MgF₂, Al₂O₃, polycarbonate (PC), poly-methylmethacrylate (PMMA), and epoxy photoresist Sub can be used. Then, an ITO layer 150 of about 200 nm as a hole transporting layer and a waveguide core layer is deposited on the waveguide lower cladding layer 170. Later, a photoresist pattern 222 is formed on the waveguide core layer 150. The details of the formation of the photoresist pattern 222 are similar to the steps described in FIGS. 11C-11F.

As shown in FIG. 12D, the excitation light source 100 consisting of sequentially stacked layers of NPB (40 nm), Alq3 (80 nm) and Al (100 nm) is deposited by evaporation over the waveguide core layer 150 and the photoresist pattern 222. Then, a protection layer 110 (50 nm) is deposited on the excitation light source 100 to protect the excitation light source stacked layers.

In FIG. 12E, a plurality of microwells 401 is formed by drilling through the excitation light source stacked layer 100 and the photoresist pattern 222 using a focused ion beam, for example. The locations of the microwells 401 correspond to the locations of the optical windows 250 in a one-to-one fashion. The bottom of the microwell exposes the top surface of the waveguide core layer 150.

In FIG. 12F, another protection layer 130 (e.g. an Al₂O₃ layer of 50 nm) is deposited conformally over the microwells 401 by atomic deposition, so as to obtain a plurality of nanowells 400. The protection layer 130 uniformly covers the sidewalls and the bottom of the nanowells 400.

According to the fabrication processes of the disclosed embodiments, the highly integrated apparatus for single molecule detection can be similarly fabricated with the excitation light source of PLED, LED, or LD. With the protection layers, the nanowell array can be integrated with the excitation light source without destroying its light performance.

The apparatus of the disclosed embodiments can be as compact as a chip having at least a light source and a detector integrated together. The arrangement of the nanowells can achieve accurate alignment for the excitation light incidence and the analyte molecule as well as for the capture of fluorescence emission by the photodetector. Furthermore, with the additional waveguide core layer and/or the waveguide lower cladding layer, the SNR is enhanced under the same input power of the excitation light source.

The apparatus of the disclosed embodiments can be applicable for single molecule detection, including real-time DNA sequencing.

It will be apparent to those skilled in the art that various modifications and variations can be made to the structure of the disclosed embodiments without departing from the scope or spirit of the invention. In view of the foregoing, it is intended that the present invention cover modifications and variations of this invention provided they fall within the scope of the following claims and their equivalents.

What is claimed is:

1. An apparatus for detecting a single molecule, comprising:
a substrate having a plurality of detectors therein;
an opaque layer with a plurality of optical windows on the substrate, wherein the optical windows align with the detectors;
an excitation light source on the opaque layer; and
a plurality of nanowells in the excitation light source for trapping the single molecule, wherein the single molecule in the nanowell is excited by the excitation light source and emits a fluorescence signal that is detected by the detector underneath the nanowell.

2. The apparatus of claim 1, wherein the excitation light source is a laser diode (LD), a solid state pumped LD, a light emitting diode (LED), an organic light emitting diode (OLED), a polymer light emitting diode (PLED), or a quantum dot light emitting diode (QLED).

3. The apparatus of claim 1, wherein the excitation light source comprises at least an emissive layer on the opaque layer, the nanowell penetrates through at least the emissive layer of the excitation light source, and the single molecule located at a bottom of the nanowell.

4. The apparatus of claim 1, wherein one of the nanowells corresponds to one of the optical windows and one of the detectors underneath the optical window.

5. The apparatus of claim 4, wherein the detector is a photodiode, a charge coupled device (CCD), a CMOS sensor, a photoconductive type optical sensor, a photovoltaic type optical sensor, an avalanche photodiode (APD), a p-n photodiode, a p-i-n photodiode or a multi junction photodiode.

6. The apparatus of claim 1, wherein a dimension of the optical window of the opaque layer is equal to or less than a dimension of the bottom of the nanowell.

7. The apparatus of claim 1, wherein a shape of a top opening of the nanowell is circular, square, triangle, rectangle or polygonal.

8. The apparatus of claim 7, wherein the shape of top opening of the nanowell is circular with a first diameter large than 1 μm and a bottom of the nanowell with a second diameter less than 200 nm.

9. The apparatus of claim 2, further comprising a waveguide lower cladding layer disposed between the excitation light source and the opaque layer.

10. The apparatus of claim 9, further comprising a waveguide core layer disposed between the excitation light source and the waveguide lower cladding layer.

11. The apparatus of claim 1, further comprising a microstructured layer disposed on a top surface of the opaque layer.

12. The apparatus of claim 1, further comprising a long-wave pass filter disposed between the opaque layer and the substrate.

13. The apparatus of claim 1, wherein the excitation light source is an organic light emitting diode (OLED) comprising an anode layer, an emissive layer disposed on the anode layer, a separation layer disposed on the emissive layer and a cathode disposed on the separation layer.

14. The apparatus of claim 1, wherein a material of the protection layer is selected from the group consisting of Al₂O₃, SiO₂, TiO₂, ZrO₂, HfO₂, Ta₂O₅, Nb₂O₅.

15. The apparatus of claim 1, wherein a material of the opaque layer is selected from the group consisting of Ti-doped Al, Al, Ti, Cr, Ag, Au, Ni, Cu, In, Pt, Pd, C, Si, Ge and Ga.

16. The apparatus of claim 1, further comprising a protection layer disposed on the excitation light source.

17. The apparatus of claim 1, further comprising a conformal protection layer covering each sidewall and a bottom of the nanowell.

18. A method for manufacturing an apparatus for single molecule detection, comprising:
providing a substrate having a plurality of detectors therein;
forming an opaque layer with a plurality of optical windows on the substrate, wherein one of the optical windows corresponds to one of the detectors;
forming a photoresist pattern on the opaque layer;
depositing an excitation light source on the opaque layer and the photoresist pattern;
forming a first protection layer over the excitation light source; and.
forming a plurality of nanowells in the excitation light source.

19. The method of claim 18, further comprising forming a second protection layer covering each sidewall and a bottom of the nanowell.

20. The method of claim 18, further comprising forming a waveguide lower cladding layer between the excitation light source and the opaque layer.

21. The method of claim 20, further comprising forming a waveguide core layer between the excitation light source and the waveguide lower cladding layer.

22. The method of claim 18, further comprising forming a microstructured layer on a top surface of the opaque layer.

23. The method of claim 18, further comprising forming a long-wave pass filter between the opaque layer and the substrate.

24. The method of claim 18, wherein one of the nanowells corresponds to one of the optical windows and one detector underneath the optical window.

25. The method of claim 18, wherein the excitation light source is a laser diode (LD), a solid state pumped LD, a light emitting diode (LED), an organic light emitting diode (OLED), a polymer light emitting diode (PLED), or a quantum dot light emitting diode (QLED).

26. The method of claim 18, wherein the excitation light source comprises at least an emissive layer on the opaque layer, the nanowell penetrates through at least the emissive layer of the excitation light source, and the single molecule located at a bottom of the nanowell.

27. The method of claim 18, wherein the detector is a photodiode, a charge coupled device (CCD), a CMOS sensor, a photoconductive type optical sensor, a photovoltaic type optical sensor, an avalanche photodiode (APD), a p-n photodiode, a p-i-n photodiode or a multi junction photodiode.

28. The method of claim 18, wherein the step of forming the excitation light source comprises forming an anode layer, forming an emissive layer disposed on the anode layer, forming a separation layer disposed on the emissive layer and forming a cathode disposed on the separation layer.
